(19) United States
(12) Patent Application Publication
(10) Pub. No.: US 2020/0098807 A1
(43) Pub. Date: Mar. 26, 2020

(54) IMAGE SENSOR MODULE AND METHOD FOR FORMING THE SAME

(71) Applicant: Ningbo Semiconductor International Corporation, Ningbo (CN)

(72) Inventor: Mengbin LIU, Ningbo (CN)

(21) Appl. No.: 16/159,140

(22) Filed: Oct. 12, 2018

Related U.S. Application Data
(63) Continuation of application No. PCT/CN2018/106869, filed on Sep. 21, 2018.

(51) Int. Cl. H01L 27/146; H04N 5/225; H05K 1/18

(52) U.S. Cl. CPC H01L 27/14618; H01L 27/14687; H04N 5/2254; H05K 2201/10151; H01L 27/14607; H05K 1/18; H01L 27/14632

(57) ABSTRACT

An image sensor module and method for forming the same are provided. A plurality of first chips is attached to a carrier wafer. A permanent bonding layer is formed on each of the plurality of first chips. The permanent bonding layer includes at least one of a patterned bonding layer and a transparent bonding layer. A second chip is bonded with each of the plurality of transparent filters via the permanent bonding layer there-between to form a plurality of package structures on the carrier wafer. The first chip is one of a transparent filter and an image sensor. The second chip is the other of the transparent filter and the image sensor. The image sensor has a photosensitive region facing the transparent filter in each package structure.

### CROSS-REFERENCES TO RELATED APPLICATIONS

This application is a continuation application of PCT Patent Application No. PCT/CN2018/106869, filed on Sep. 21, 2018, the entirety of which is incorporated herein by reference.

### FIELD OF THE DISCLOSURE

The present disclosure generally relates to the field of image sensors and, more particularly, relates to image sensor modules and methods for forming the same.

### BACKGROUND

Camera modules are widely used in various mobile terminals, such as mobile phones, personal digital assistants, and laptops. Conventional camera modules are often formed by first attaching a chip of a complementary metal oxide semiconductor (CMOS) image sensor on a printed circuit board (PCB). Then, a holder is used to hold an infrared (IR) filter. The holder and the IR filter together are bonded with the image sensor by a dispensing process. Finally, a motor and a lens are mounted on the holder.

Problems arise, however, because the image sensor attached to the PCB is directly exposed to the ambient environment and its photosensitive area may be easily contaminated during packaging. Such contaminations may cause imaging defects. In addition, after the image sensor is attached to the PCB, the holder with the held IR filter may then be bonded with the image sensor. The design of structure and size of such holder is thus constrained.

The disclosed image sensor modules and their methods are directed to solve one or more problems set forth above and other problems in the art.

### BRIEF SUMMARY OF THE DISCLOSURE

According to various embodiments, there is provided a method for forming an image sensor module. In the method, a plurality of first chips is attached to a carrier wafer. A permanent bonding layer is formed on each of the plurality of first chips. The permanent bonding layer includes at least one of a patterned bonding layer and a transparent bonding layer. A second chip is bonded with each of the plurality of transparent filters via the permanent bonding layer there-between to form a plurality of package structures on the carrier wafer. The first chip is one of a transparent filter and an image sensor. The second chip is the other of the transparent filter and the image sensor. The image sensor has a photosensitive region facing the transparent filter in each package structure.

According to various embodiments, there is also provided an image sensor module. The image sensor module includes a plurality of first chips; a permanent bonding layer on each of the plurality of first chips, and a second chip bonded with each of the plurality of first chips via the permanent bonding layer there-between to form a plurality of package structures. The permanent bonding layer includes at least one of a patterned bonding layer and a transparent bonding layer. The first chip is one of a transparent filter and an image sensor and the second chip is the other of the transparent filter and the image sensor. The image sensor has a photosensitive region facing the transparent filter in each package structure.

Other aspects or embodiments of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIGS. 1-2, 3A-3B, 4A-4C, 5, 6A-6B, and 8 illustrate structures corresponding to certain stages during a method for forming an exemplary image sensor module according to various embodiments of the present disclosure;

FIGS. 7A-7B illustrate exemplary package structures used for image sensor modules according to various embodiments of the present disclosure;

FIG. 9 illustrates an exemplary method for forming an image sensor module according to various embodiments of the present disclosure;

FIGS. 10, 11A-11C, 12, 13A-13B, and 15 illustrate structures corresponding to certain stages during a method for forming another exemplary image sensor module according to various embodiments of the present disclosure; and

FIGS. 14A-14B illustrate another exemplary package structures used for image sensor modules according to various embodiments of the present disclosure.

### DETAILED DESCRIPTION

Reference will now be made in detail to exemplary embodiments of the disclosure, which are illustrated in the accompanying drawings. Wherever possible, the same reference numbers will be used throughout the drawings to refer to the same or like parts.

The present disclosure provides image sensor modules and methods for forming the image sensor modules. For example, a plurality of first chips is attached to a carrier wafer. A permanent bonding layer is formed on each of the plurality of first chips. A second chip is bonded with each of the plurality of transparent filters via the permanent bonding layer there-between to form a plurality of package structures on the carrier wafer. The permanent bonding layer includes at least one of a patterned bonding layer and a transparent bonding layer. In some embodiments, the first chip is one of a transparent filter and an image sensor. The second chip is the other of the transparent filter and the image sensor. The image sensor has a photosensitive region facing the transparent filter in each package structure.

For illustration purposes, the present disclosure is primarily described, taking the transparent filter as an example of the first chip and the image sensor as an example of the second chip, while the first and second chips may be interchangeably used in the disclosed image sensor modules and their methods, according to various embodiments of the present disclosure.

For example, transparent filters (or image sensors) may be attached to a carrier wafer, e.g., by a temporary bonding layer or using an electrostatic bonding process. A permanent bonding layer, such as a patterned bonding layer or a transparent bonding layer, may be formed on the transparent filters (or image sensors). An image sensor (or a transparent filter) is attached onto the permanent bonding layer and thus bonded with each transparent filter (or each image sensor). The transparent filter, the image sensor, and the permanent bonding layer form a package structure over the carrier wafer.

In some embodiments, the carrier wafer may then be removed. The formed package structures may be transferred, transported, stored, and/or further assembled for any use as desired. For example, after removing the carrier wafer, the package structure may be placed over a printed circuit board (PCB) and a lens assembly may be mounted over the package structure to form an exemplary image sensor module. In one embodiment, the PCB can be rigid or flexible.

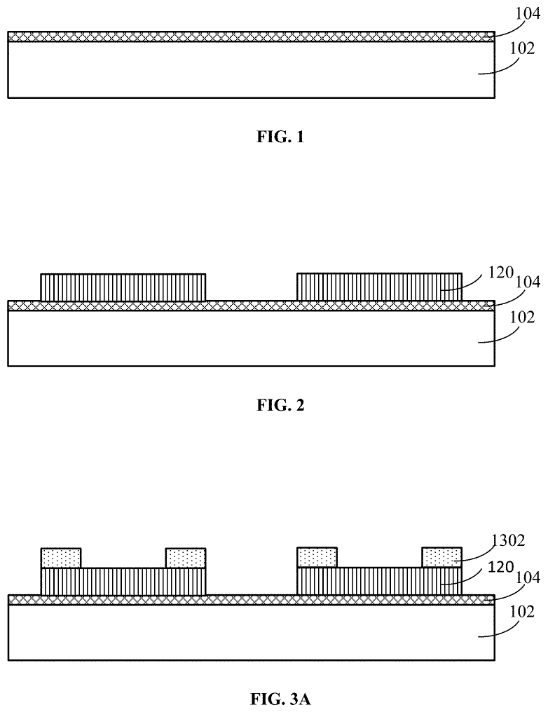

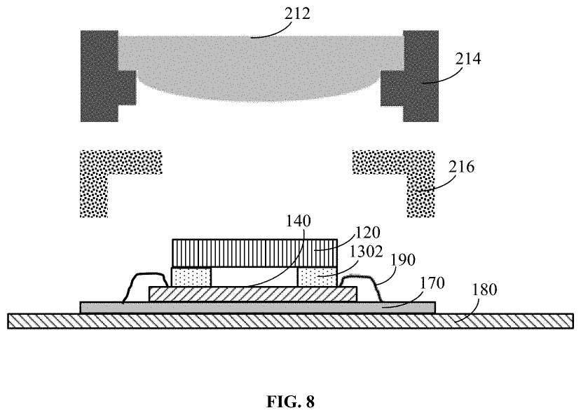

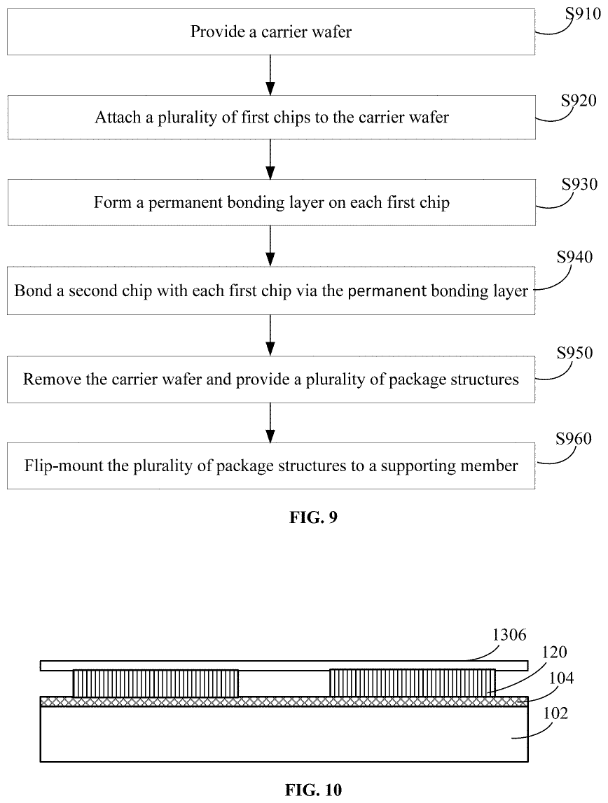

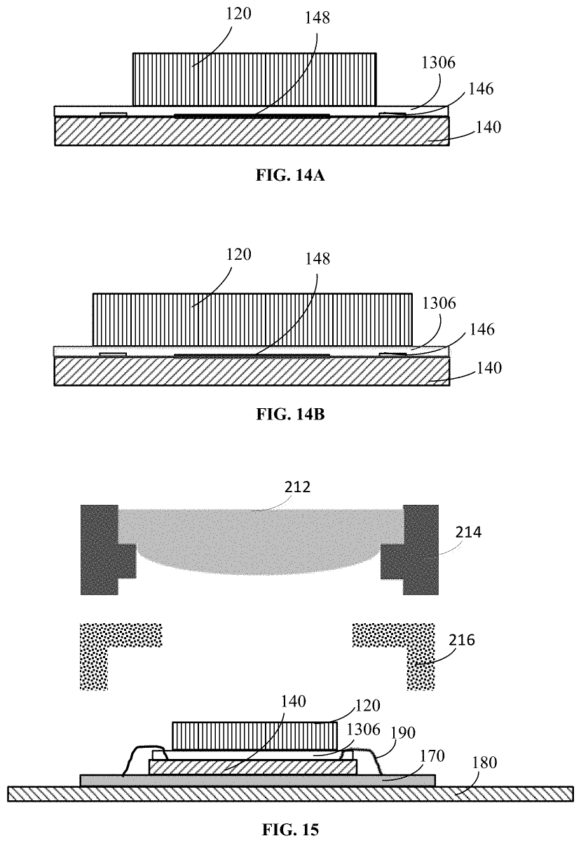

According to various embodiments of the present disclosure, FIGS. 1-2, 3A-3B, 4A-4C, 5, 6A-6B, and 8 illustrate structures corresponding to certain stages during a method for forming an exemplary image sensor module, while FIGS. 10, 11A-11C, 12, 13A-13B and 15 illustrate structures corresponding to certain stages during a method for forming another exemplary image sensor module. FIGS. 7A-7B and FIGS. 14A-14B illustrate various package structures for forming exemplary image sensor modules. FIG. 9 illustrates an exemplary method for forming image sensor modules.

Referring to FIG. 9, for forming an exemplary image sensor module, a carrier wafer is provided (e.g., in S910). FIG. 1 illustrates a corresponding structure.

As shown in FIG. 1, a carrier wafer 102 is provided. The carrier wafer 102 may be made of a material including, for example, silicon, glass, silicon oxide, aluminum oxide, or combinations thereof. The carrier wafer 102 may have a thickness ranging from about 350 μm to about 1000 μm. In some cases, the carrier wafer 102 may have a diameter of about 200 mm, about 300 mm, etc.

Still in FIG. 1, optionally, a temporary bonding layer 104 may be applied on the carrier wafer 102. The temporary bonding layer may include, for example, a thermal-release layer or any suitable temporary bonding layer that is able to provide support for the packaging process of the package structure and that may be released after forming the package structure.

The temporary bonding layer 104 may provide an adhesive mechanism capable of adhering chips/dies/wafers onto the carrier wafer 102. The temporary bonding layer 104 may be applied to the carrier wafer 102, for example, using a lamination process, a coating process, a printing process, etc. The temporary bonding layer 104 may have a thickness ranging from about 50 μm to about 150 μm. The temporary bonding layer 104 may include a polymer, such as a thermoplastic or a thermos-elastic material. The temporary bonding layer 104 may include a single-layered structure or a multi-layered structure.

In the embodiments when a thermal-release layer is used, the thermal-release layer may include, for example, a multi-layered structure. The multi-layered structure may include, for example, a foaming adhesive layer, a pressure sensitive layer, and a polymer film such as a polyester film, sandwiched between the foaming adhesive layer and the pressure sensitive layer. Additionally, a release liner layer may be included on each of the foaming adhesive layer and pressure sensitive layer. For example, before the thermal-release layer is attached to the carrier wafer, a corresponding release liner layer may be removed.

The foaming adhesive layer may become foaming when heated, which allows release or removal of, for example, the carrier wafer from the temporary bonding layer. In some embodiments, the thermal-release layer is a double-sided adhesive layer having the above described multi-layered structure.

In another example, the thermal-release layer may be a thermal-release tape, having an adhesion substantially equivalent to a normal adhesive tape at room temperatures, which can be easily peeled off when required, e.g., simply by heating. Heat used for the removal can be selected, for example, about 90° C., 120° C., 150° C., 170° C., or any suitable temperature based on the material(s) used for the temporary bonding layer 104.

Referring back to FIG. 9, in S920, a plurality of transparent filters may be attached to the carrier wafer. FIG. 2 illustrates a corresponding structure.

As shown in FIG. 2, transparent filters 120 may be attached or otherwise bonded to the carrier wafer 102, with or without using the temporary bonding layer 104.

The transparent filters 120 may be substantially optically transparent and may include, for example, a glass chip. For example, the transparent filters 120 may include an IR glass chip having an IR filter function.

The transparent filters 120 may be singulated chips. The transparent filters 120 may be positioned on the carrier wafer 102 in a manner such that the transparent filters are spaced apart from one another by a predetermined distance sufficient for the packaging process. In some embodiments, several dozens of the transparent filters 120 or several hundreds of transparent filters 120 or more may be attached to the temporary bonding layer 104, depending on the size of the transparent filters 120, the size of carrier wafer 102, and the particular applications.

In one embodiment, a global alignment may be used to align and attach the transparent filters 120 to the carrier wafer 102. For example, in a global alignment, marks within the kerf outside the chips are used at two positions of the carrier wafer to bring the carrier wafer to the transparent filters. For example, the alignment accuracy may be less than about 5 microns.

Various methods may be used to attach the transparent filters to the carrier wafer, including, for example, a pick and place process, an electrostatic bonding process, etc.

For example, a pick and place machine may be used to place the transparent filters 120 in the predetermined locations on the temporary bonding layer 104 of the carrier wafer 102. Pressure may also be applied to the temporary bonding layer 104, e.g., from the carrier wafer 102 upwardly to the transparent filters 120, from the transparent filters 120 downwardly to the carrier wafer 102, or a combination thereof.

In an exemplary embodiment, the transparent filters 120 may be attached to the temporary bonding layer 104 at room temperatures under a pressure of about 0.2 N to about 10 N, such as about 0.2 N to about 5 N, for each chip and for about 0.1 second to about 30 seconds, such as about 0.5 second to about 5 seconds.

In another example, without using any temporary bonding layer, the transparent filters 120 may be placed in the predetermined locations on the carrier wafer 102 by an electrostatic bonding process. In other words, the temporary bonding layer 104 may be omitted.

In the electrostatic bonding process, the carrier wafer may be connected to a positive electrode of a power supply, and the transparent filters may be connected to a negative electrode of the power supply. A voltage may then be applied. The transparent filter/carrier wafer may be heated. When the voltage is applied, a large electrostatic attraction between the carrier wafer (such as a silicon wafer) and the transparent filter (such as a glass chip) may bring the two into close contact for the bonding.

Referring back to FIG. 9, in S930, a permanent bonding layer, e.g., including a patterned bonding layer or a transparent bonding layer, may be formed on the transparent filters.

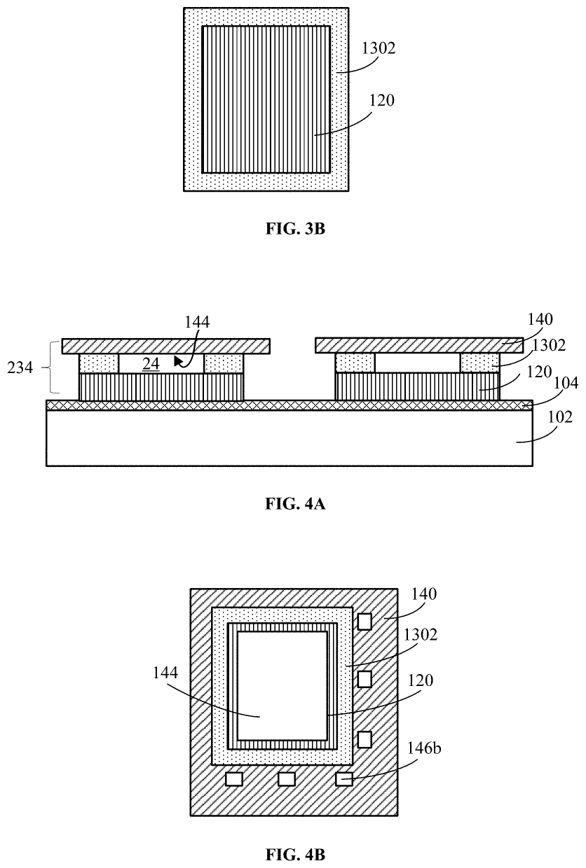

In some embodiments, the permanent bonding layer may be a patterned bonding layer, e.g., as illustrated in FIG. 3A-3B; and in other embodiments, the permanent bonding layer may be a transparent bonding layer, e.g., as illustrated in FIG. 10, although any suitable bonding layer(s) may be used herein for forming the package structure according to various embodiments of the present disclosure.

As shown in FIGS. 3A-3B, a patterned bonding layer 1302 may be formed on a corresponding transparent filter 120. For example, referring to FIG. 3B, the patterned bonding layer 1302 may be formed on the transparent filter 120 as a cofferdam surrounding or enclosing at least a partial surface area of the transparent filter 120.

The patterned bonding layer 1302 formed on each transparent filter may later be aligned with a photosensitive region of a subsequently bonded image sensor. The patterned bonding layer 1302 may have a width for each pattern, for example, greater than about 50 μm to provide sufficient support and stability for subsequently bonding the transparent filter with an image sensor. The patterned bonding layer 1302 may have a thickness, based on a surface of the transparent filter 120, ranging from about 20 μm to about 1000 μm, e.g., from about 20 μm to about 600 μm, or from about 20 μm to about 60 μm. The patterned bonding layer 1302 may include a single-layered structure or a multi-layered structure. The thickness of the patterned bonding layer 1302 may depend on a distance between the transparent filter 120 and a subsequently bonded chip, such as an image sensor chip.

In some embodiments, the patterned bonding layer 1302 may be formed by a photolithographic process. For example, the patterned bonding layer may include a patterned dry film. The patterned dry film may be formed by forming a dry film on each transparent filter, and patterning the dry film by the photolithographic process to form the patterned dry film.

When the patterned bonding layer 1302 is a patterned dry film, the patterned dry film may include a multi-layered structure having a photosensitive layer sandwiched between polymer layers including, for example, a polyethylene terephthalate (PET) layer and a polyester (PE) layer, or between any suitable polymer layers. The photosensitive layer may include monomers of photosensitive materials, photo initiators, polymer binder, and additives (e.g., promoters and dyes). The monomers are the components of the patterned bonding layer.

In an exemplary photolithographic process, a dry film may be applied on surfaces of the transparent filters 120, optionally the temporary bonding layer 104, and any exposed area of the carrier wafer 102, under a vacuum pressure of about 50 Pa to about 500 Pa at a temperature of about 80° C. to about 130° C. The dry film may be pre-baked at about 110° C. to about 150° C. for about 80 seconds to about 200 seconds, followed by an exposure process at a radiant energy density of about 800 mJ/cm² to about 1500 mJ/cm².

After the exposure process, the patterned dry film may be further baked at a temperature of about 110° C. to about 150° C. for about 80 seconds to about 200 seconds, followed by a development process in an isopropanol alcohol (IPA) solution for about 100 to about 300 seconds, or in a propylene glycol monomethyl ether acetate (PGMEA) solution for about 60 seconds to about 200 seconds, followed by an IPA rinse process.

In other embodiments, the patterned bonding layer 1302 may be formed by a screen printing process. Any suitable material(s) may be used to form the patterned bonding layer by the screen printing process. Non-limited examples for the materials include a structural glue, a UV-double-sided bonding layer, a transparent glue, or any combinations thereof. The structural glue may be, for example, an epoxy adhesive, such as a two-component flexible epoxy resin adhesive.

In the embodiments when the patterned bonding layer 1302 is a UV-double-sided bonding layer for bonding the transparent filters with the image sensors, a UV-curable precursor may be coated and then patterned on the transparent filters. It should be noted that the UV-curable precursor may be patterned using any process that does not involve UV radiation and/or heat. For example, the UV-curable precursor may not be patterned by a photolithographic process. Instead, a screen printing process or any processes without involving heat and UV radiation may be used to pattern UV-curable precursor on each transparent filter.

In one embodiment, the UV-curable precursor may have the patterns as similarly shown in FIG. 3A. The patterned UV-curable precursor may later be cured and solidified, after the image sensor is applied thereon. After curing, the transparent filter may be bonded with the corresponding image sensor. Depending on the materials used for UV-curable precursor, a UV radiation may be used to form the UV-curable bonding layer.

In the embodiment when an electrostatic bonding process is used to attach the transparent filters to the carrier wafer, a screen printing process may be more suitably used (e.g., compared with a photolithographic process which may affect the electrostatic bonding between the transparent filters and the carrier wafer) for forming the patterned bonding layer 1302 as the permanent bonding layer on each transparent filter.

The disclosed permanent bonding layer may include a transparent bonding layer. For example, referring to FIG. 10, a transparent bonding layer 1306 may be formed on the transparent filters 120. The transparent bonding layer 1306 may be attached, e.g., to fully or partially cover all of the transparent filters 120, on an entire surface of the carrier wafer 102. In some embodiments, the transparent bonding layer 1306 may be “singulated” or cut into a plurality of transparent bonding layer portions (not illustrated), with each individual portion corresponding to one package structure.

The transparent bonding layer 1306 may be a double-sided adhesive layer, prepared to receive image sensors to bond each image sensor with a corresponding transparent filter.

Referring back to FIG. 9, in S940, an image sensor may be bonded with a corresponding transparent filter by attaching the image sensor to the permanent bonding layer on the transparent filter. As such, the transparent filter and the image sensor are bonded to form a package structure on the carrier wafer.

In some embodiments, the image sensor may be, for example, a CIS chip including a CMOS image sensor or a charge-coupled device (CCD) image sensor.

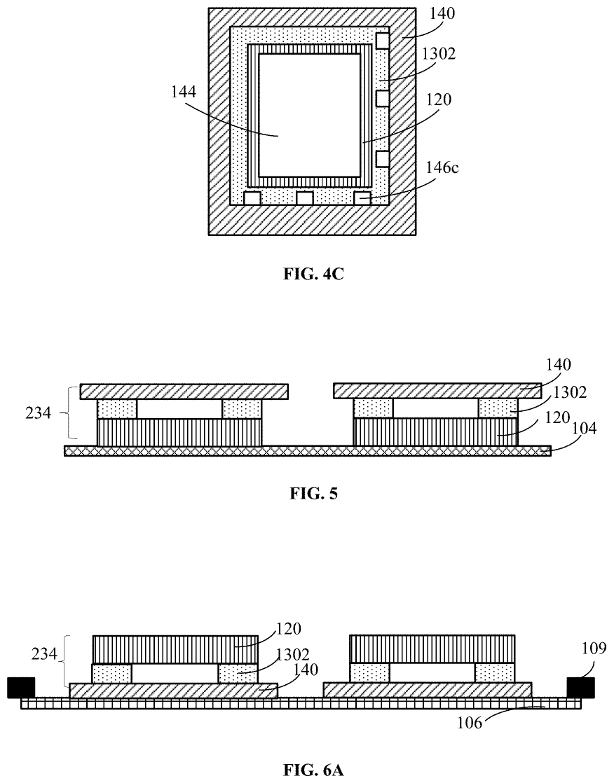

In some embodiments, as illustrated in FIGS. 4A-4C, the package structure includes a cavity enclosed by, a transparent filter, an image sensor, and a patterned bonding layer. FIG. 4A illustrates package structures based on the structure illustrated in FIG. 3A, and FIGS. 4B-4C illustrate top view projections of exemplary package structures projected on the carrier wafer.

As shown in FIGS. 4A-4C, an image sensor 140 may be bonded with the patterned bonding layer 1302 on each transparent filter 120 to form a package structure 234 having a cavity 24 therein.

A front-side of the image sensor 140 may have a photosensitive region 144 and a pad region having a plurality of connection pads 146b/c, as shown in FIGS. 4B-4C. The connection pads 146b/c may be used to connect the image sensor 140 with corresponding external circuit(s).

In one embodiment, the image sensor 140 may be front-side down having photosensitive region 144 aligned with the region enclosed by the patterned bonding layer 1302 on the transparent filter 120, and then bonded with the patterned bonding layer 1302 on the transparent filter 120. Such bonding process may include a baking process. During the bonding process, the alignment accuracy may vary depending on specific applications. For example, when aligning the image sensor 140 with the patterned bonding layer 1302, the photosensitive region 144 of the image sensor 140 may be aligned or positioned, within alignment accuracy, corresponding to the surface area on the transparent filter 120 that is enclosed by the patterned bonding layer 1302.

In one embodiment, the image sensor 140 may be aligned and attached with the patterned bonding layer 1302 at a temperature of about 130° C. to about 170° C. for about 0.1 minute to about 5 minutes, such as about 0.5 minute to about 5 minutes, followed by a baking process at a temperature of about 160° C. to about 200° C. for about 0.5 hour to about 3 hours.

The photosensitive region 144 of the image sensor 140 may thus be exposed within the cavity 24 and inner facing the transparent filter 130. The photosensitive region 144 of the image sensor 140 may be protected from the ambient environment, for example, may be protected from particle contaminations, starting at the early stages of the disclosed packaging process.

As shown in the top view projections of the package structures 234 in FIGS. 4B-4C, in the cavity 24, the photosensitive region 144 of the image sensor 140 may have an area smaller than and within an area of the transparent filter 120. In some cases, the cavity 24, the photosensitive region 144, the exposed area of the transparent filter 120, and/or the patterned bonding layer 1302 may be coaxially centered, although any suitable configurations may be included in accordance with various embodiments of the present disclosure.

In some embodiments as shown in FIG. 4B (e.g., also in FIG. 7A), the plurality of connection pads 146b formed on the image sensor 140 may be outside of the bonding area where the patterned bonding layer 1302 is bonded with the image sensor 140. For example, the connection pads 146b may be at least partially surrounding the bonding area between the bonded transparent filter 120 and image sensor 140.

In other embodiments as shown in FIG. 4C (e.g., also in FIG. 7B), the plurality of connection pads 146c formed on the image sensor 140 may be at least partially overlapped with the bonding area between the image sensor 140 and the transparent filter 120. For example, the patterned bonding layer 1302 may be bonded with the image sensor 140 at a position that is at least partially on the connection pads 146c of the image sensor 140. As a result, the plurality of connection pads 146c may be at least partially sandwiched between the image sensor 140 and the transparent filter 120.

As such, once the image sensor 140 having connection pads 146 are formed, the patterned bonding layer 1302 may be formed inside the connection pads 146 or partially/wholly on the connection pads 146 of the image sensor 140. In some cases, to allow sufficient space for the photosensitive region 144 to be well packaged within the cavity 24, the width of the patterned bonding layer 1302 may be adjusted. For example, the patterned bonding layer 1302 in FIG. 4B (e.g., also in FIG. 7A) may have a width less than the patterned bonding layer 1302 in FIG. 4C (e.g., also in FIG. 7B). In other cases, the overall size and structure of the package structures may be adjusted (e.g., see FIG. 14A), and the size and shape of the cavities in different package structures may be different.

The connection pads may be made of copper, gold, copper-nickel alloy, copper-silver alloy, copper-gold alloy, solder, tin-silver, or a combination thereof.

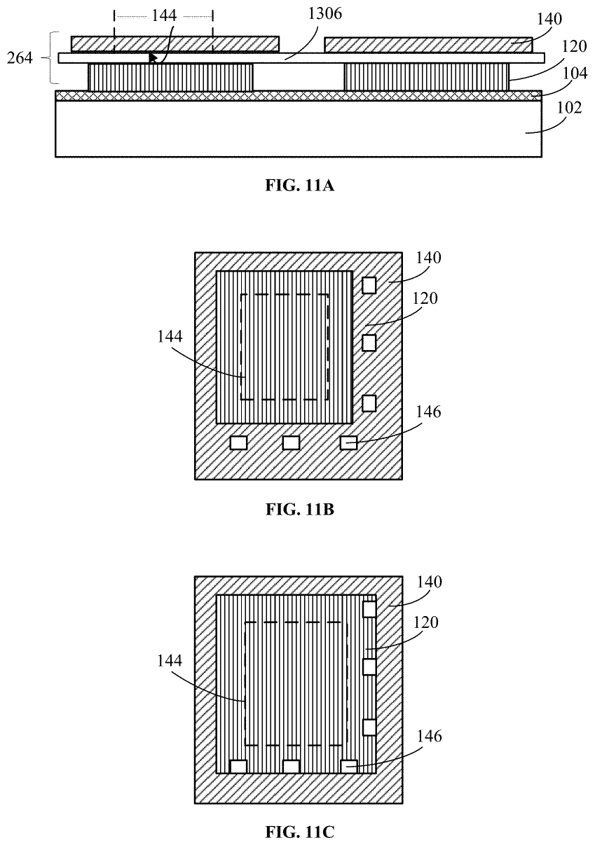

In some embodiments, the formed package structure may not include a cavity. For example, as illustrated in FIGS. 11A-11C, a package structure 264 may include a transparent filter 120 and an image sensor 140, bonded by a transparent bonding layer 1306. FIG. 11A illustrates package structures based on the structure illustrated in FIG. 10, and FIGS. 11B-11C illustrate top view projections of exemplary package structures projected on the carrier wafer.

As shown in FIGS. 11A-11C, an image sensor 140 may be bonded with the transparent bonding layer 1306 on each transparent filter 120 to form a package structure 234. The transparent bonding layer 1306 may be fully or partially cover all of the transparent filters 120, on an entire surface of the carrier wafer 102. In some embodiments, the transparent bonding layer 1306 may be “singulated” or cut into a plurality of transparent bonding layer portions (not illustrated), with each individual portion corresponding to one package structure.

A distance between the image sensor 140 and the transparent filter 120 in the package structure 234 may equal to a thickness (or less) of the transparent bonding layer 1306.

A front-side of the image sensor 140 may have a photosensitive region 144 and a pad region, the pad region having a plurality of connection pads 146b/c. The connection pads 146b/c may be used to connect the image sensor 140 with corresponding external circuit(s).

In one embodiment, the image sensor 140 may be front-side down having photosensitive region 144 aligned with a corresponding region on the transparent filter 120 within alignment accuracy. The photosensitive region 144 of the image sensor 140 may thus be inner facing the transparent filter 120. The photosensitive region 144 of the image sensor 140 may be protected from the ambient environment, for example, may be protected from particle contaminations, starting at the early stages of the disclosed packaging process.

In some embodiments as shown in FIG. 11B (e.g., also in FIG. 14A), the plurality of connection pads 146b on the image sensor 140 may be outside of a bonding area between the image sensor 140 and the transparent filter 120. For example, the connection pads 146b may be formed at least partially surrounding the bonded transparent filter 120.

In other embodiments as shown in FIG. 11C (also in FIG. 14B), the plurality of connection pads 146c of the image sensor 140 may be aligned and at least partially overlapped with the bonding area between the image sensor 140 and the transparent filter 120. For example, the plurality of connection pads 146c may be at least partially sandwiched between the image sensor 140 and the patterned bonding layer 1302 for bonding with the transparent filter 120.

Referring back to FIG. 9, in S950, the carrier wafer may be removed, providing a plurality of package structures. FIG. 5 illustrates a corresponding structure.

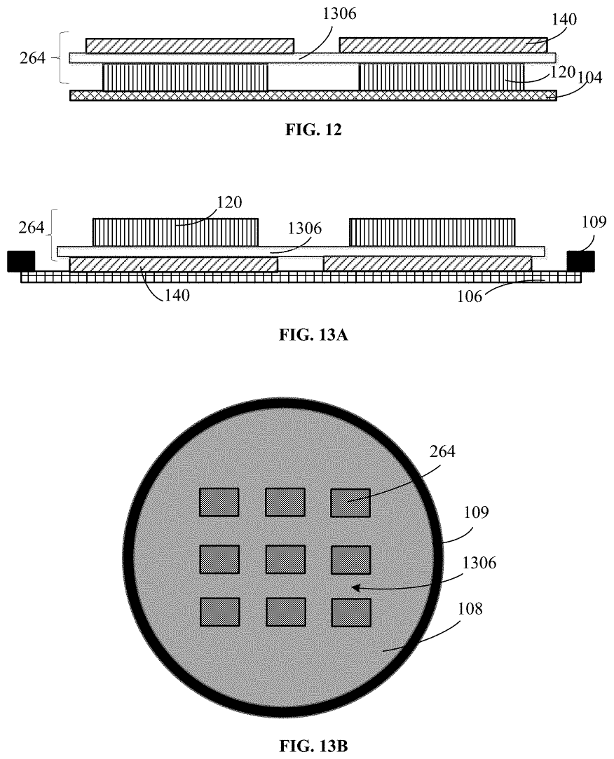

As shown in FIGS. 5 and 12, the carrier wafer 102 may be removed from the transparent filters 120, leaving package structures 234/264 on the temporary bonding layer 104. For example, depending on the materials used, the temporary bonding layer 104 may be heated to release the carrier wafer 102 to de-bond the carrier wafer 102 from the temporary bonding layer 104. In one embodiment, the heating temperature is about 150° C. to about 250° C. for about 1 minute to about 10 minutes for the de-bonding.

In another example where the temporary bonding layer is omitted and the transparent filter is bonded with the carrier wafer by an electrostatic bonding process, the carrier wafer may be released from the transparent filters by, for example, removal of the voltage applied between the transparent filters and the carrier wafer.

Referring back to FIG. 9, in S960, the plurality of package structures may be flip-mounted to mount the image sensors onto a supporting member.

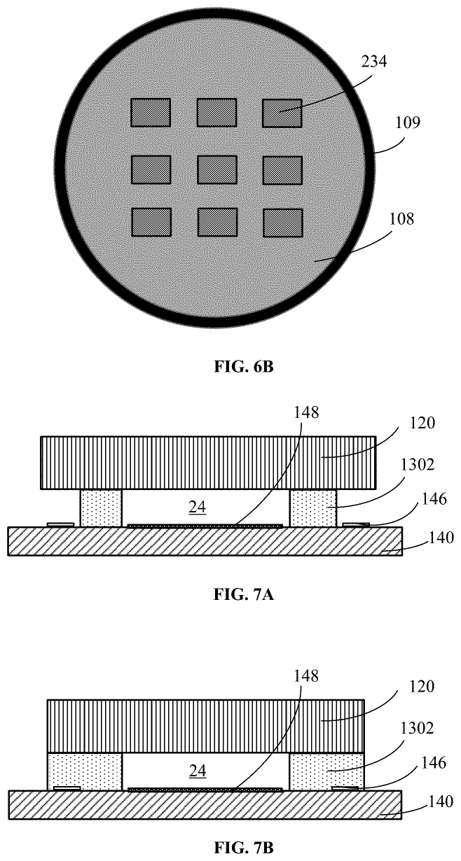

As shown in FIGS. 6A-6B and FIGS. 13A-13B, each package structure 234/264 may be flipped over to mount the image sensors 140 onto a supporting member 106, e.g., via an adhesive tape 108 on the supporting member 106. In addition, a frame 109 may be placed over the supporting member 106 via the adhesive tape 108. The frame 109 may be at least partially over the supporting member 106. The frame 109 may be in an annual shape surrounding the plurality of package structures 234 on the supporting member 106.

In various embodiments, the adhesive tape 108 on the supporting member 106 may be the same or different from the temporary bonding layer 104, although any suitable adhesive tape may be used herein. In some cases, when the transparent filter 120 is an IR glass chip, a surface film may be removed from the glass chip after flip-mounting the package structures 234/264.

The package structures 234/264 may be flip-mounted onto the supporting member 106 at room temperatures for transferring, transporting, storing, and/or further assembling of the package structures 234/264 for a subsequent use.

FIGS. 7A-7B illustrates exemplary package structures 234, and FIGS. 14A-14B illustrates exemplary package structures 264, according to various embodiments of the present disclosure. The package structures include a chip size package (CSP).

As shown, the image sensor 140 may have a front-side, including a photosensitive region 144 and a plurality of connection pads 146.

In a package structure 234 illustrated in FIGS. 7A-7B, the photosensitive region 144 of the image sensor 140 is exposed within the cavity 24 and facing the transparent filter 120 surrounded by the patterned bonding layer 1302 and may thus be protected from contaminations from ambient environment. Micro lens 148 may be disposed on the photosensitive region of the image sensor 140 and may have an area smaller than an area of the transparent filter 120 exposed in the cavity 24.

In a package structure 264 illustrated in FIGS. 14A-14B, the photosensitive region 144 of the image sensor 140 is attached to the transparent bonding layer 1306 and facing the transparent filter 120, and may thus be protected from contaminations from ambient environment. Micro lens 148 may be disposed on the photosensitive region of the image sensor 140.

In the package structure 234/264, the connection pads 146 on the image sensor 140 are used for connecting the image sensor 140 with corresponding external circuit(s).

In some embodiments as shown in FIGS. 7A and 14A, the connection pads 146 of the image sensor 140 may be outside of the bonding area between the image sensor 140 and the transparent filter 120, e.g., at least partially surrounding the bonding area. In some cases, the overall size and structure of the package structures may be adjusted. The size and shape of the cavities in different package structures may be different. For example, the patterned bonding layer 1302 in FIG. 7A (e.g., also in FIG. 4B) may have a reduced width for bonding the transparent filter 120 with the image sensor 140. In another example, as shown in FIG. 14A, smaller transparent filter 120 may be bonded with the image sensor 140 having connection pads 146 of the image sensor 140 outside of the bonding area.

In other embodiments as shown in FIGS. 7B and 14B, the connection pads 146 on the image sensor 140 may be at least partially sandwiched between the image sensor 140 and the transparent filter 120.

FIGS. 8 and 15 illustrate an exploded view of exemplary image sensor modules including a package structure according to various embodiments of the present disclosure. Examples of the package structure may include those illustrated in FIGS. 4A-4C, 5, 6A-6B, 7A-7B, 11A-11C, 12, 13A-13B, and 14A-14B.

For example, the package structure 234/264 may be placed on a connection layer 170, which may be placed on a printed circuit board (PCB) 180.

In the package structure, connection pads (e.g., as shown in FIGS. 4B-4C, 7A-7B, 11B-11C, and 14A-14B) of the image sensor 140 may be outside of the bonding area and connected to bonding wires 190. The bonding wires 190 may provide electrical connections between the image sensor 140 of the package structure and the PCB 180 via the connection layer 170. Optionally, the bonding wires 190 may be covered by a protection material or a molding (not shown).

The image sensor modules in FIGS. 8 and 15 may further include a lens assembly. The lens assembly includes a lens 212, a lens barrel 214, and/or a supporting element 216. The lens barrel 214 is configured to be adjustable such that the focal length of the lens 212 may change.

The supporting element 216 may be mounted on the connection layer 170 (and/or the printed circuit board 180), over and surrounding the package structure on the connection layer 170. The supporting element 216 may be configured between the lens barrel 214 and the connection layer 170 (and/or the printed circuit board 180). The supporting element 216 may be used to mechanically support the lens barrel 214 over the disclosed package structure.

Unlike conventional holder for holding a glass chip, the supporting element 216 does not hold any chip(s) and may have a more simplified structure and reduced dimensions. For example, a height of the simplified supporting element 216 in the lens assembly of the image sensor module may be reduced, e.g., by about 0.4 mm or less. In addition, the supporting element 216 may be made of a material including, for example, a plastic, a rubber, a ceramic, and any other suitable materials.

In this manner, a package structure may be formed in chip size by first bonding a transparent filter and an image sensor together. The photosensitive region of the image sensor is inner faced to the transparent filter within each package structure, and is thus protected from contaminations from the ambient environment during subsequent processes. The yield of the package structures is therefore increased.

In addition, the disclosed modules and methods may allow use of a simplified supporting element in the lens assembly of the image sensor module, because the chips are bonded together to form the package structure first and there is no need for the supporting element to hold any chip(s).

Various embodiments also include mobile terminals, such as mobile phones, personal digital assistants, and/or laptops, which contain the disclosed image sensor modules with simplified structures and reduced sizes.

The embodiments disclosed herein are exemplary only. Other applications, advantages, alternations, modifications, or equivalents to the disclosed embodiments are obvious to those skilled in the art and are intended to be encompassed within the scope of the present disclosure.

What is claimed is:

1. A method for forming an image sensor module, comprising:
attaching a plurality of first chips to a carrier wafer;
forming a permanent bonding layer on each of the plurality of first chips, wherein the permanent bonding layer includes at least one of a patterned bonding layer and a transparent bonding layer; and
bonding a second chip with each of the plurality of first chips via the permanent bonding layer there-between to form a plurality of package structures on the carrier wafer,
wherein the first chip is one of a transparent filter and an image sensor and the second chip is the other of the transparent filter and the image sensor, and the image sensor has a photosensitive region facing the transparent filter in each package structure.

2. The method according to claim 1, further including:
removing the carrier wafer after bonding the second chip.

3. The method according to claim 2, further including:
mounting the plurality of second chips of the plurality of package structures to a printed circuit board (PCB) after removing the carrier wafer, the PCB including a rigid PCB or a flexible PCB.

4. The method according to claim 1, wherein:
the image sensor has a front-side, the front-side including:
the photosensitive region, and
a plurality of connection pads on or outside a bonding area of the image sensor bonded with the transparent filter.

5. The method according to claim 1, wherein:
when the permanent bonding layer is the transparent bonding layer, a distance between the first and second chips in the package structure equals to a thickness or less of the transparent bonding layer.

6. The method according to claim 5, wherein:
the transparent bonding layer includes a transparent glue.

7. The method according to claim 5, wherein:
the transparent bonding layer covers the plurality of first chips on an entire surface of the carrier wafer.

8. The method according to claim 1, wherein:
when the permanent bonding layer is the patterned bonding layer,
the patterned bonding layer, the image sensor, and the transparent filter together enclose a cavity within each package structure, wherein the photosensitive region of the image sensor is exposed within the cavity.

9. The method according to claim 1, further including:
forming the patterned bonding layer by a photolithographic process.

10. The method according to claim 9, wherein the patterned bonding layer includes a patterned dry film, formed by:
forming a dry film on each first chip, and
patterning the dry film by the photolithographic process to form the patterned dry film.

11. The method according to claim 1, further including:
forming the patterned bonding layer by a screen printing process,
wherein the patterned bonding layer includes a structural glue, a UV-double-sided bonding layer, a transparent glue, or a combination thereof.

12. The method according to claim 1, wherein attaching the plurality of first chips to the carrier wafer includes:
applying a temporary bonding layer onto the carrier wafer, and
attaching the plurality of first chips to the temporary bonding layer.

13. The method according to claim 12, wherein:
the temporary bonding layer includes a thermal-release layer,
the thermal-release layer is a double-sided adhesive layer having a multi-layered structure, and
the multi-layered structure includes a foaming adhesive layer, a pressure sensitive layer, and a polymer film sandwiched between the foaming adhesive layer and the pressure sensitive layer.

14. The method according to claim 1, wherein:
attaching the plurality of first chips to the carrier wafer includes an electrostatic bonding process, and
forming the permanent bonding layer on each of the plurality of first chips includes a screen printing process.

15. The method according to claim 1, wherein, when the permanent bonding layer includes a UV-double-sided bonding layer, forming the permanent bonding layer on each of the plurality of first chips, and bonding the second chip with each of the plurality of transparent filters include:
coating a UV-curable precursor on each first chip,
patterning the UV-curable precursor by a screen printing process,
placing the second chip on the UV-curable precursor on each first chip, and
curing the UV-curable precursor between the first and second chips to form the UV-double-sided bonding layer as the permanent bonding layer.

16. The method according to claim 1, wherein bonding the second chip with each of the plurality of first chips via the permanent bonding layer there-between includes:
bonding the image sensor with each of the plurality of transparent filters via a patterned dry film at a temperature of about 130° C. to about 170° C. for about 0.1 minute to about 5 minutes.

17. The method according to claim 3, further including:
mounting a lens assembly over each package structure, wherein:
the lens assembly includes a supporting element mounted on the printed circuit board (PCB) over the package structure.

18. An image sensor module, comprising:
a plurality of first chips;
a permanent bonding layer on each of the plurality of first chips, wherein the permanent bonding layer includes at least one of a patterned bonding layer and a transparent bonding layer; and
a second chip bonded with each of the plurality of first chips via the permanent bonding layer there-between to form a plurality of package structures,
wherein the first chip is one of a transparent filter and an image sensor and the second chip is the other of the transparent filter and the image sensor, and the image sensor has a photosensitive region facing the transparent filter in each package structure.

19. The image sensor module according to claim 18, wherein:
the image sensor has a front-side, the front-side including:
the photosensitive region, and
a plurality of connection pads on or outside of a bonding area of the image sensor bonded with the transparent filter.

20. The image sensor module according to claim 18, wherein:
when the permanent bonding layer is the patterned bonding layer, the permanent bonding layer is made of a material including a dry film, a structural glue, a UV-double-sided bonding layer, a transparent glue, or a combination thereof, and
when the permanent bonding layer is the transparent bonding layer, a distance between the first and second chips in the package structure equals to a thickness or less of the transparent bonding layer, and the transparent bonding layer includes a transparent glue, covering all of the plurality of first chips.
